(19) United States
(12) Patent Application Publication
(10) Pub. No.: US 2007/0229790 A1
(43) Pub. Date: Oct. 4, 2007

(54) Arrangement for the transfer of structural elements of a photomask onto a substrate and method therefor

(76) Inventors: Bernd Kuechler, Radeberg OT Liegau Augustusbad (DE); Thomas Muelders, Dresden (DE); Rainer Pforr, Dresden (DE); Joerg Tschischgale, Dresden (DE)

Correspondence Address: SLATER & MATSIL, L.L.P., 17950 PRESTON ROAD, SUITE 1000, DALLAS, TX, 75252, US

(21) Appl. No.: 11/728,181

(22) Filed: Mar. 23, 2007

(30) Foreign Application Priority Data
Mar. 23, 2006 (DE) 10 2006 013 459.1

(51) Int. Cl. G03F 7/20; G03B 27/42

(52) U.S. Cl. 355/53; 430/311

(57) ABSTRACT

An arrangement for the transfer of structural elements of a photomask onto a substrate includes an illumination device, a photomask with a plurality of structural elements, wherein radiation from the illumination device transfers the structural elements of the photomask onto a photoresist placed on a substrate, and an optical element, wherein the optical element produces a local variation in the degree of transmission of the radiation.

This application claims priority to German Patent Application 10 2006 013 459.1, which was filed Mar. 23, 2006, and is incorporated herein by reference.

### TECHNICAL FIELD

Arrangement for the transfer of structural elements of a photomask onto a substrate and method for the transfer of structural elements of a photomask onto a substrate.

### BACKGROUND

The invention under consideration concerns an arrangement for the transfer of structural elements of a photomask onto a substrate. Furthermore, the invention concerns a method for the transfer of structural elements of a photomask onto a substrate.

With the progressive miniaturization of integrated circuits, components with increasingly small structure sizes on a substrate are needed. To this end, a predetermined pattern of a mask is transferred onto a substrate in a lithographic process. Nowadays, structures of a few tens of nm in width and length are transferred onto wafer surfaces. In competition with other semiconductor manufacturers, both the throughput and also the precision of the transfer are decisive in economic success. The throughput is ensured by a “step and scan” method. However, defects in the precision of the structure transfer, in particular, in the control of the length and width of the structures to be portrayed, reduce the yield of functional chips.

Two main sources are responsible for inaccuracies during the structure transfer. Both mask inaccuracies as well as nonuniformities over the image field, caused by the projection system, contribute to undesired variation in the structure dimensions on the wafer. Mask defects are, above all, with high Mask Error Enhancement Factor (MEEF) values (≧3.5), which are to be typically expected with small kl factors, of decisive influence on the structure size control. This applies, above all, to the critical chip structures, whose line widths are characterized by the “Critical Dimension” (CD). If we are not dealing with lines, but rather two-dimensional structures, such as contact holes, then both their width as well as their length, or their width and the aspect ratio, which is determined by the relationship of width to length, must be controlled.

In order to ensure an improvement in the structure size control, high demands are placed on the structure size precision on the mask with high MEEF values. In this way, the costs of mask production are driven up. Therefore, attempts are being made to find ways to improve the structure size control by other methods that do not involve a considerable rise in manufacturing costs for lithographic masks.

An approach to improved CD control provides for correcting the illumination dose during the scanning process. First, the CD variation over the image field is measured and a dose matrix is prepared, which contains an optimal dose for each point in the image field. The dose along the scanning direction can be modulated by varying the scanning rate or by varying the pulse dose. Furthermore, a modulation of the dose can be effected along the slit direction by introducing gray filters. In a mathematical sense, dose variation Δ dose in the form Δ dose=f₁(X)×f₂(Y) can be realized for the two-dimensional illumination field with the X and Y coordinate directions, where, for example, f₁(X) describes the dose variation along the scanning direction, and f₂(Y) the dose variation along the slit direction, realized by means of gray filters.

In general, the optimal dose, doseₒₚₜ(X, Y), can be approximated only more or less poorly by a dose variation Δdose=f₁(X)×f₂(Y) in the product form. In practice, the dose variation along the scanning direction f₁(X) caused by the high scanning rates, which can be up to 500 mm/s, is inaccurately adjustable. This makes it difficult to approximate the optimal dose distribution, if, as is common in practice, comparatively high CD variations along the scanning direction in the image field, which are based on mask defects, are to be corrected. With this method, the aspect ratios, such as hole width to hole length, cannot be controlled with two-dimensional structures, such as contact holes, even if a good approximation of the optimal dose is possible.

Thus, an adjustment of the local dose in the illumination field may adjust the width of a contact hole to its theoretical value, but it will also change the possibly previously corrected length of the contact hole. In general, therefore the control of both the length and the width of two-dimensional structures will be required. This, however, is impossible with an adjustment of the dose adapted locally in the illumination field.

This characteristic of not being able to control simultaneously both the length and the width of two-dimensional structures is common to the method with many other previously proposed possibilities for CD control.

Another method for CD control provides for adjusting the intensity distribution of the light striking the mask, in accordance with the previously measured line width distribution in the illumination field by local manipulation of the refractive index and the absorption coefficient of the glass carrier. By means of a laser beam, the local refractive index and the absorption variations in the glass carrier are thereby introduced. With illumination with actinic light, fractions of the light intensity are removed from the beam path of the projection system by absorption and light scattering. By variation of the spatial density of the introduced variations of the refractive index and absorption coefficient, the intensity effective on the mask plane can be subjected to fine-grain modulation. In particular, intensity or dose variations of the general form Δdose (X, Y), that is, not only as for the method described above in the product form Δdose=f₁(X)×f₂(Y), can be introduced. The CD correction accuracy is accordingly greater.

With the method, the entire system, mask-illumination system and projection objective, can be optimized. CD variations caused by the projection system can also be automatically corrected, which leads to a limited usability of the corrected masks. Thus, the mask adapted by this method cannot be used if it is used in another projection objective or when using another illumination in the same projection objective, if CD variations caused by the projection objective or the individually used illumination adjustment cannot be neglected. That leads to the masks having to be re-written specifically for the projection objective, wherein new costs arise. Like the above-described irradiated dose adjustment with an additional gray filter in the slit direction, it is also impossible to correct both the length and the width of two-dimensional structures simultaneously.

Another method consists in separating the mask and the correcting element physically from one another. A transparent optical element, which modulates the effective intensity on the plane of the mask structures, either by means of laser beams or by placement of light-absorbing structures, is thereby introduced before the mask. The transparency of the light-absorbing structures, adjusted to the previously measured CD variation on the wafer plane, thereby permits a homogenization of the structure sizes on the wafer plane. At the same time, by the physical separation of the mask and the correcting element, it becomes possible to use masks in individually different projection objectives. Only the correcting elements must then be replaced when using the same or a similar mask in individually different projection objectives or when using another illumination adjustment. The costs are reduced by the feasibility of using multiple masks.

Here, just as with the previously described methods, only the effective intensity or the dose can be modulated, whereby it is not possible to correct the homogeneity of the length and the width for two-dimensional structures.

Therefore, there is the demand to further improve arrangements and methods for the transfer of structural elements of a photomask onto a substrate.

### SUMMARY OF THE INVENTION

An embodiment of an arrangement for the transfer of structural elements of a photomask onto a substrate comprises an illumination device which produces radiation, a photomask with a plurality of structural elements, whereby the radiation from the illumination device transfers the structural elements of the photomask onto a photoresist placed on a substrate. The arrangement moreover comprises an optical element, wherein the optical element produces a local variation of a degree of transmission of the radiation.

An embodiment of a method for the transfer of structural elements onto a substrate comprises the provision of a photomask with a plurality of structural elements, a substrate on which a photoresist is formed, an optical element, and an illumination device that produces radiation for the transfer of the structural elements of the photomask. The method, moreover, comprises the placement of the optical element between the photomask and the substrate or between the illumination device and the photomask, the transfer of the structural elements of the photomask onto the photoresist formed on the substrate, wherein the optical element produces a local variation of a degree of transmission of the radiation.

An embodiment of a method for the transfer of structural elements onto a substrate comprises the provision of a photomask with a plurality of structural elements placed thereon, a first substrate on which a photoresist is formed, and an illumination device that produces radiation for the transfer of the structural elements of the photomask. The method also comprises the transfer of the structural elements of the photomask onto the photoresist formed on the first substrate and the measurement of the image elements on the first substrate, obtained by the transfer of the structural elements of the photomask onto the photoresist formed on the first substrate. The method comprises, moreover, the determination of deviations of the obtained image elements on the first substrate in comparison with nominal structures, the production of an optical element that corrects the deviation of the obtained image elements on the first substrate in comparison with the nominal structures, a second substrate on which a photoresist is formed, the placement of the optical element between the photomask and the second substrate or between the illumination device and the photomask, and the transfer of the structural elements of the photomask onto the photoresist that is formed on the second substrate, wherein the optical element causes a local variation in the degree of transmission of the radiation.

Other advantageous embodiments of an arrangement for the transfer of structural elements of a photomask onto a substrate and the method for the transfer of structural elements onto a substrate are possible and are apparent to one skilled in the art from the following detailed description of the embodiment examples.

### BRIEF DESCRIPTION OF THE DRAWINGS

Embodiments of the arrangement for the transfer of structural elements of a photomask onto a substrate and embodiments of the method for the transfer of structural elements onto a substrate are explained in more detail, below with reference to the drawings. Shown are:

FIG. 1, a schematic representation of an arrangement in accordance with an embodiment;

FIG. 2, schematically, the attenuation of individual orders of diffraction of the radiation after passage through the optical element;

FIG. 3a, a top view of a two-dimensional mask structure of a photomask;

FIG. 3b, the diffraction pattern of the mask structure of the photomask shown in FIG. 3a, which arises with light normally incident on to the photomask plane;

FIG. 3c, the illumination pupil of an illumination device 4, in the form of a quadrupole illumination device;

FIG. 3d, the result of convolution of the frequency spectrum of the photomask, in accordance with FIG. 3a, with the intensities of the areas of the quadrupole illumination device, in accordance with FIG. 3b;

FIG. 4, schematically, a rotationally symmetrical pupil filter, whose transparency is reduced towards the outside;

FIG. 5a, a top view of a resist contour in a photoresist, which one obtains with a structure transfer of a rectangular dark structure on the photomask without the use of stacked antireflection layers;

FIG. 5b, a top view of a resist contour in a photoresist which one obtains with a structure transfer of a rectangular dark structure on the photomask, using stacked antireflection layers;

FIGS. 6a and 6b, an example of the transmission behavior of stacked antireflection layers;

FIGS. 7a, 7b, and 7c, an example of the transmission behavior of stacked antireflection layers; and

FIG. 8, an arrangement in which an optical element is placed between an illumination device and a photomask.

### DETAILED DESCRIPTION OF ILLUSTRATIVE EMBODIMENTS

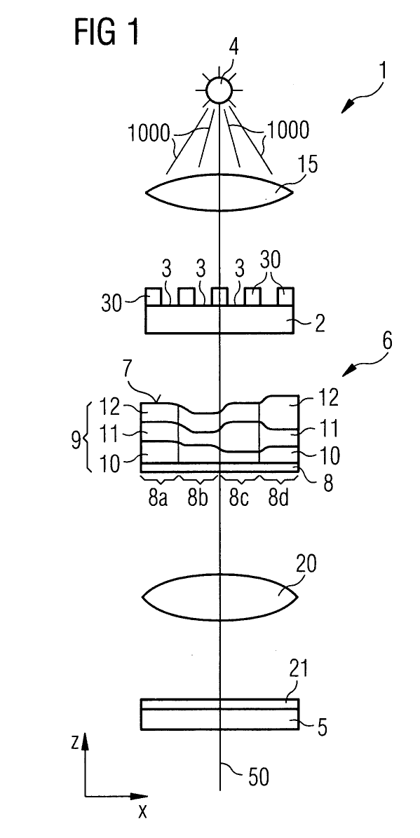

FIG. 1 shows an arrangement 1, in accordance with an embodiment. The arrangement 1 comprises an illumination device 4, a first lens system 15, a photomask 2, an optical element 6, a second lens system 20, and a substrate 5, which are arranged along an optical axis 50 of the first lens system 15 and the second lens system 20. It is preferred that the first lens system 15, the photomask 2, the optical element 6, the second lens system 20, and the substrate 5 be used, arranged vertically with respect to the optical axis 50.

The first lens system 15 is placed between the illumination device 4 and the photomask 2. The optical element 6 is placed between the photomask 2 and the second lens system 20. The second lens system 20 is placed between the optical element 6 and the substrate 5.

The illumination device 4 comprises a light source, which produces ultraviolet (UV) or deep ultraviolet (DUV-Deep UltraViolet) light, or another type of radiation, which is suitable for a photolithographic process. The light source can comprise, for example, an ArF laser, which generates light with a wavelength of 193 nm. The illumination device 4 can be designed to produce an oblique illumination of the photomask 2. This can be produced, for example, by an arrangement of one or more light sources at a distance from the optical axis 50. The illumination device 4 for the production of an oblique illumination can, for example, comprise a dipole illumination device, a quadrupole illumination device, or an annular (ring-shaped) illumination device.

The photomask 2 comprises a mask pattern with structural elements 3, which are to be transferred onto the substrate 5. The photomask 2 typically comprises a thin quartz plate, on which dark structures 30, such as light-absorbing elements, for example, chromium, and light-attenuating elements, such as molybdenum-silicate, are applied.

The optical element 6 can be connected firmly with the photomask 2 in that it is placed, for example, on a pellicle frame of the photomask 2. Alternatively, the optical element 6, however, can also be affixed with the aid of an arrangement independent of the photomask 2, between the photomask 2 and the second lens system 20. The optical element 6 has a carrier 8, which can be made of an optically transparent material, such as quartz glass. At least one antireflection layer stack 9 is placed on a surface of the carrier 8, facing the photomask 2. The at least one antireflection layer stack 9, however, can also be placed on a surface of the carrier 8, turned away from the photomask 2.

The stacked antireflection layers 9 can comprise several layers. The stacked antireflection layers 9 can comprise a first layer 10, which is placed on the surface of the carrier 8, a second layer 11, placed on the first layer 10, and a third layer 12, placed on the second layer 11. The radiation falling on the stacked antireflection layers 9 is attenuated, as a function of the angle of incidence of the radiation, with respect to a surface 7 of the optical element 6.

The substrate 5 can comprise a wafer, which is coated with a photoresist (photosensitive coating) 21, so that after carrying out a photolithographic process, an image of the mask pattern on the photosensitive coating 21 is produced on the wafer.

When operating the arrangement 1, a radiation 1000, produced by the illumination device 4, passes the first lens system 15, the photomask 2, the optical element 6, and the second lens system 20, and projects an image of the mask pattern onto the photoresist 21, which is placed on the substrate 5. The photoresist 21 can then be developed or etched, so as to produce a resist contour of the photoresist 21. The resist contour of the photoresist 21 can be transferred to the substrate 5 by etching processes known in the art.

The mask pattern of the photomask 2 leads to a situation in which the radiation, incident on the photomask 2, is split up, behind the photomask 2, into diffraction orders. The diffraction orders are present in the far radiation field, behind the photomask 2, in an angular distribution, specific to the mask pattern and the illumination device 4.

The diffraction orders of the radiation, incident on the stacked antireflection layers 9 and diffracted at the photomask 2, are attenuated as a function of the shape of the stacked antireflection layers 9 and as a function of the angle of incidence of the radiation with respect to the surface 7 of the optical element 6.

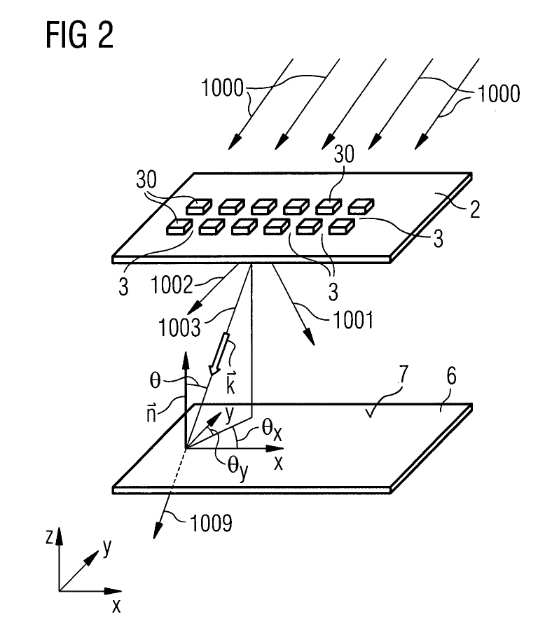

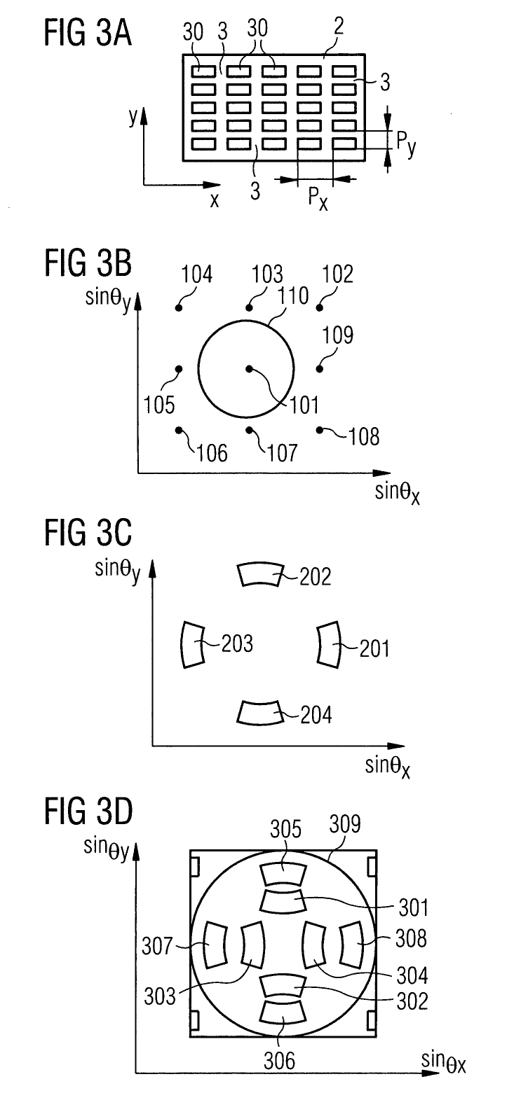

The carrier 8 of the optical element 6 is made up of several sections 8a, 8b, 8c, 8d. Some of the stacked antireflection layers 9, with different layer thicknesses for the first layer 10, the second layer 11, and the third layer 12, are formed on individual sections 8a, 8b, 8c, 8d of the carrier. The individual sections 8a, 8b, 8c, 8d of the carrier 8, and the corresponding stacked antireflection layers 9 are associated with individual areas on the surface of the substrate 5, wherein the association is determined by the specific shape of the arrangement 1. Local pupil filters, effective for individual sections in the illumination field, are realized by the development of the carrier 8 with several sections 8a, 8b, 8c, 8d, which have some of the stacked antireflection layers 9; the filters permit the correction of both the length and the width of two-dimensional structures of the photoresist 21 in accordance with a previously measured nonhomogeneity of length and width distributions of the structures of the photoresist 21 on the substrate 5. The mode of operation of the pupil filter is explained in more detail in the description, with reference to FIGS. 2 and 3. With this arrangement, it is possible to not only effect intensity modulations that influence both the lengths and widths of two-dimensional structures of the photoresist 21, and thus avoid individual corrections of the length and width of two-dimensional structures of the photoresist 21; but also to adjust length and width corrections over the illumination field independently of one another. This arrangement permits the local correction of the aspect ratio in the illumination field both with polarized irradiation and also when using unpolarized light.

In order to ensure that the layer thickness variations of the individual stacked antireflection layers 9 can be adjusted locally on the carrier, a laser-aided, chemical vapor deposition method (CVD), for example, can be used for the formation of the individual layers. The local temperature distribution and thus the local deposition rate of the layer material is influenced by a locally variable intensity irradiation of the laser. Thus, it is possible to adjust the thickness of the layer material to be deposited locally, in a purposeful manner and accurate to a nanometer.

Another possibility is the placement of diaphragms (“stencils”) with variable openings before the carrier 8 to be coated or to move it under such stencils, while controlling the time. Thus, the material flow of the layer material to be deposited can be controlled locally on the carrier 8 and, in this way, an exact layer thickness control can be achieved. However, other methods can also be used to apply the layers on the carrier 8.

For the mode of operation of the optical element 6, described above, it is important that with the individual method, the required layer thickness variations can be adjusted to several nm to 10 nm. Lesser demands are thereby made of the spatial resolution of the local layer thickness variations. It is sufficient if the layer thickness control primarily attains a lateral resolution in the range of approximately 0.1 to 1 nm.

FIG. 2 shows, schematically, the attenuation of individual diffraction orders of the radiation 1000 after passage through the optical element 6. The radiation 1000 strikes the photomask 2 at an angle with respect to a photomask surface of the photomask 2. The radiation 1000 is diffracted at structural elements 3 of the photomask 2, so that various diffraction orders 1001 to 1003 of the radiation are present in the far radiation field behind the photomask 2, after passage through the photomask 2. The diffraction orders 1001 to 1003 are present in an angular distribution specific to the structural elements 3 and the illumination device 4.

The standardized wave vector [symbol] gives the direction of propagation of the diffraction order 1003 of the radiation 1000, directly before the optical element 6. The diffraction order 1003 of the radiation 1000 strikes the optical element 6 at an angle θ, with respect to the surface 7 of the optical element 6. If the x and y components of the normalized wave vector z,1 are designated as \vec{k}ₓ=sin(\textcircled{x}ₓ) and \vec{k}_{y}=sin(\textcircled{x}_{y}), then the result of the normalization is \vec{k}_{z}=−{square root over (1−(sin²(\textcircled{x}ₓ+sin²(\textcircled{x}_{y})). A thickness modulation of the stacked antireflection layers 9 (not shown in FIG. 2) of the optical element 6 can be so slight that a surface normal [symbol] of the stacked antireflection layers 9 (not shown in FIG. 2) can always be assumed in the z direction, \vec{n}=(0,0,1)^{T}. Then, \vec{k}·\vec{n}=\vec{k}_{z}−cos(\textcircled{x}) is valid, and for this reason, results in sin²(\textcircled{x})=sin²(\textcircled{x}ₓ)+sin²(\textcircled{x}_{y}). Since the transparency of the stacked antireflection layers 9 depends only on the angle of incidence θ, for given thicknesses of the first layer 10, the second layer 11, and the third layer 12, the transparency function describes a radial pupil filter, which is a function only of the radius coordinate r=sin(\textcircled{x})={square root over (sin²\textcircled{x}ₓ)+sin²(\textcircled{x}_{y}) in the pupil plane, defined by the direction cosines \vec{k}ₓ=sin(\textcircled{x}ₓ) and \vec{k}_{y}=sin(\textcircled{x}_{y}). Reference symbol 1009 illustrates the attenuated diffraction order 1003 after passage through the optical element 6.

FIG. 3a shows a top view of the two-dimensional mask structure and a two-dimensional mask pattern of a photomask 2. The mask structure comprises two-dimensional, periodic dark structures 30 with structure periods placed vertically with respect to one another and two-dimensional, periodic structural elements 3, with structure periods placed vertically with respect to one another. Adjacent structural elements 3 have a first distance (pitch) pₓ along a first direction X, and adjacent structural elements 3 have a second distance p_{y} along a second direction Y, wherein the first distance pₓ is different from the second distance p_{y}. The first distance pₓ=220 nm and the second distance p_{y}=180 nm in the example under consideration.

FIG. 3b shows the diffraction pattern 101 to 109 of the mask structure of the photomask 2, which are formed with light normally incident on the photomask plane in a representation in which the diffraction intensities are plotted versus the angles or the direction cosines sin θₓ and sin θ_{y} of the diffraction orders. This representation illustrates the frequency spectrum of the photomask 2, which is present in the exit pupil plane.

As a result of the lower pitch p_{y} along the Y direction, in comparison with the pitch pₓ along the X direction, the diffraction orders 103 and 107 are at a shorter distance from the central diffraction order 101 than the diffraction orders 105 and 109.

The circle 110 symbolizes the maximum opening of an objective of the arrangement 1 (not shown in FIG. 3b). With the light normally incident on the photomask plane, only those diffraction orders 101 which lie within this circle 110 contribute to the structure transfer onto the photosensitive resist 21 on the substrate 5. Diffraction orders 102 to 109 lying outside the circle 110 do not contribute to the structure transfer. With radiation incident of at an obtuse angle, the diffraction orders corresponding to the direction cosine of the incident radiation is shifted, in this representation, by said direction cosine.

FIG. 3c illustrates the frequency spectrum of an illumination device 4, which is designed as a quadrupole illumination device, in a pupil representation, wherein the frequency spectrum is plotted versus the angles and the direction cosines sin θₓ and sin θ_{y}. The areas 201 to 204 thereby represent the intensities of the illumination device 4 in the illumination pupil.

FIG. 3d shows the result of a convolution of the frequency spectrum of the photomask 2, in accordance with FIG. 3a, which characterizes the intensity of the diffraction orders with normally incident light, with the intensities of the areas 201, 202, 203, 204 of the quadrupole illumination device, in accordance with FIG. 3b. This representation symbolizes the intensity distributions of the diffraction orders in an entry pupil plane of the second lens system 20 and is designated as a pupil filling. Due to the oblique illumination, diffraction orders of the photomask 2, which do not contribute to the structure transfer with normally incident of light, also contribute to the structure transfer. The areas 305 to 308 result from the convolution of the intensities of the areas 201 to 204, shown in FIG. 3c, with the diffraction pattern 101 of the photomask, shown in FIG. 3b. The area 301 results from the convolution of the intensity of the area 204, shown in FIG. 3c, with the diffraction pattern 103 of the photomask, shown in FIG. 3b; the area 302 results from the convolution of the intensity of the area 202, shown in FIG. 3c, with the diffraction pattern 107 of the photomask, shown in FIG. 3b; area 303 results from the convolution of the intensity of the area 201, shown in FIG. 3c, with the diffraction pattern 105 of the photomask, shown in FIG. 3b; and the area 304 results from the convolution of the intensity of the area 203, shown in FIG. 3c, with the diffraction pattern 109 of the photomask, shown in FIG. 3b.

The areas 303 and 304 of the pupil filling, lying further inside, are associated with the pitch pₓ; the areas 301 and 302 of the pupil filling lying further outside are associated with the pitch p_{y}.

The circle 309 symbolizes the maximum opening of an objective of the arrangement 1. Areas lying outside this circle 309 do not contribute to the structure transfer.

In accordance with one embodiment, an optical element 6, with stacked antireflection layers 9, which produces an angle-dependent transmission modulation, is found behind the photomask 2. Depending on the angle of incidence of the diffraction orders, with respect to the surface 7 of the optical element 6, the intensity of the individual diffraction order is modulated, wherein the stacked antireflection layers 9 act as a rotationally symmetrical pupil filter. The individual transparency as a function of the angle of incidence can thereby be adjusted purposefully by the layer thicknesses of the individual layers 10, 11, 12 of the stacked antireflection layers 9. Since the layer thicknesses of the individual layers 10, 11, 12 of the stacked antireflection layers 9 can be varied locally, that is, as a function of the lateral position behind the photomask 2, a specifically adapted pupil filter is realized for each position in the image field.

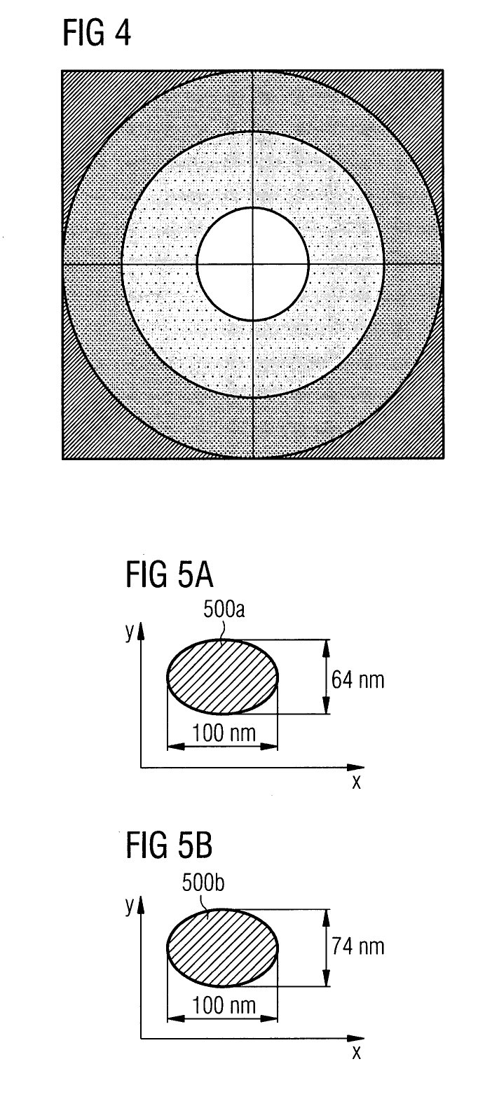

FIG. 4 shows, schematically, a rotationally symmetrical pupil filter, which has a transparency that decreases towards the outside. In FIG. 4, dark areas illustrate low transparency, and light areas high transparency.

The pupil filter has a multiplicative effect on the pupil filling. The example shown in FIGS. 3a, 3b, 3c, 3d, and 4 makes it possible for the areas 301, 302 lying further outside to be more intensely attenuated than the areas 303, 304 lying further inside. The more intensely attenuated pupil areas belong to the structure period along the second direction Y of the photomask. When this pupil filter is used, the result is an extension of the structure of the photosensitive resist 21 on the photomask 2 along the second direction Y, relative to the dimensions in the first direction X.

FIG. 5a shows a top view of a resist contour 500a in a photoresist placed on a substrate obtained with a transfer of structural elements placed on a photomask, without the use of stacked antireflection layers, in accordance with one embodiment. The resist contour 500a thereby represents the image of a rectangular dark structure 30 of the photomask and can be designated as an image element of the structure transfer located on the substrate. The rectangular dark structure is a dark structure of an arrangement of dark structures on the photomask, placed periodically along the X and Y directions, as shown, for example, in FIG. 3a.

The extent of the resist contour along the X direction is 100 nm and the extent of the resist contour along the Y direction is 64 nm.

The resist contour 500a, obtained by the structure transfer, is then compared with a nominal structure. The dimensions of the nominal structure in the X and the Y directions are the lengths of a resist contour that one would like to obtain with a structure transfer of the rectangular dark structure. For example, it may be desirable to extend the length of the resist contour in the Y direction. However, it may also be desirable to extend the length of the resist contour in the X direction.

In order to effect the desired change in the ratio of the length of the resist contour in the X direction to that in the Y direction, an optical element is produced, which enables the lengths of the resist contour to be corrected in accordance with the desired nominal structure. In the example under consideration, it is desired that the length of the resist contour be extended in the Y direction. To this end, the optical element is designed with at least one antireflection layer stack, wherein the layer thicknesses of the individual layers of the antireflection layers stacked are designed in such a way that the stacked layers act as a pupil filter with a transparency that decreases towards the outside.

Another substrate with a photoresist placed thereon is provided, and the optical element is placed between the photomask and the other substrate.

Then a transfer of the structural elements of the photomask onto the photoresist placed on the other substrate is performed. The result of this structure transfer is shown in FIG. 5b, which shows a top view of a resist contour 500b in the photoresist on the other substrate. The extent of the resist contour in the X direction is 100 nm and that in the Y direction is 74 nm.

The aspect ratio, which is determined by the ratio of the width in the Y direction to the width in the X direction, is 0.64 for the case without a pupil filter, whereas it is increased to 0.74 when using the pupil filter.

The pupil filter therefore produces an extension of the structure width in the second direction Y, relative to the structure width in the first direction X. If the reverse is desired, i.e., an extension of the structure width in the first direction X relative to the structure width in the second direction Y, then a pupil filter is used in which the regions 301 and 302 of the pupil area, shown in FIG. 3d, that have a higher transparency lie further inside the pupil area than the regions 303 and 304, shown in FIG. 3d.

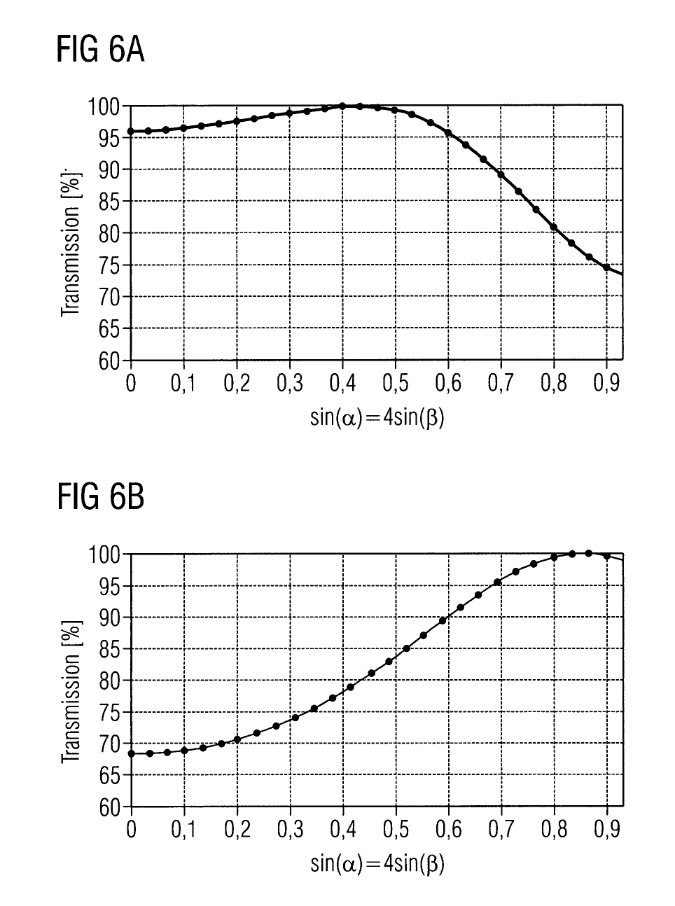

FIG. 6a shows the transmission behavior of an example of stacked antireflection layers, which attentuate the structure periods (large pupil coordinates of the corresponding diffraction orders). The transmission is shown as a function of radial pupil coordinate sin α in the exit pupil plane, which is typically four times larger, with an enlargement factor of M=4, than radial pupil coordinate sin β in the entry pupil plane of the second lens system 20; that is, in the plane directly behind the optical element. The first layer of the stacked antireflection layers is made of magnesium fluoride and has a layer thickness of 1877.6 nm. The second layer is made of tantalum pentoxide and has a layer thickness of 855.7 mm. The third layer is made of magnesium fluoride and has a layer thickness of 1660.7 nm.

FIG. 6b shows the transmission behavior of another example of stacked antireflection layers, which attenuates diffraction orders lying further inside in the pupil. The first layer of the antireflection layer stack is made of magnesium fluoride and has a layer thickness of 1346.8 nm. The second layer is made of tantalum pentoxide and has a layer thickness of 388.6 nm. The third layer is made of magnesium fluoride and has a layer thickness of 1711.5 nm.

By adjusting the layer thicknesses of the individual layers of the stacked antireflection layers, it is possible to realize almost any pupil filter. In this way, the aspect ratio for contact holes can be easily affected.

If a thin plate that can be covered with the layer system is not originally provided in the optical design, then care must be taken that the carrier of the optical element on which the stacked antireflection layers are to be applied be formed only very thinly. Otherwise, aberrations are induced which can no longer be simply corrected.

The design of the stacked antireflection layers, that is, the layer thicknesses of the individual layers and the layer sequence, can be designed in such a way that the spherical aberrations induced by the carrier of the optical element are corrected at the same time that the required angle-dependent transmission modulation is corrected. In order to effect both corrections, the transmission modulation and the compensation of the spherical phase errors, stacked antireflection layers which consist of more than three layers may also be required.

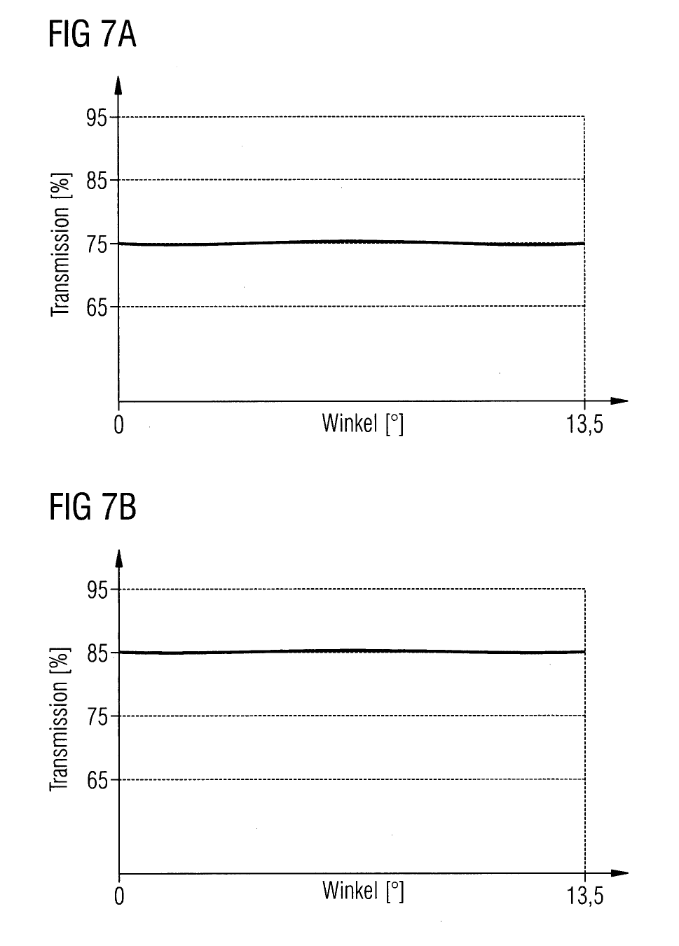

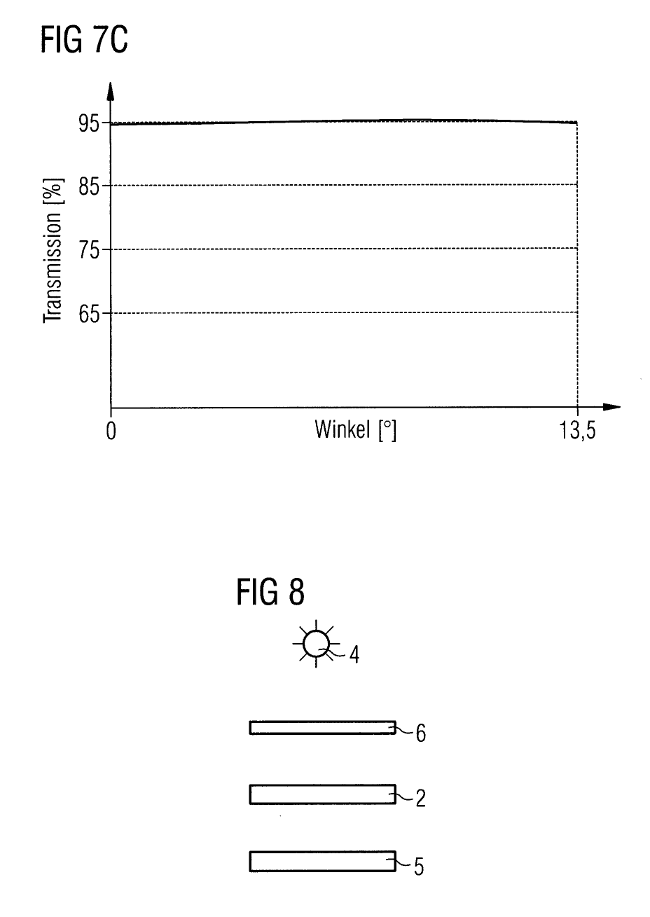

With reference to FIGS. 7a, 7b, and 7c, it is also possible to realize optical elements 6, with which as uniform as possible a transmission through the stacked antireflection layers 9 is attained, independently of the angle of incidence of the radiation on the stacked antireflection layers 9. In this case, that is, for a uniform modulation of the transmission to be adjusted over the entire angular range, the layer stack can also be placed before the photomask 2, for example, between the illumination device 4 and the photomask 2, or between the first lens system 15 and the photomask 2. The complication of making available a sufficiently thin carrier 8 of the optical element 6, so that only correctable aberrations are induced is thereby eliminated.

FIGS. 7a, 7b, and 7c show the transmission behavior of an individual stacked antireflection layers 9, with respect to the angle of incidence. The indicated angle range of 0° to 13.5° corresponds to the maximum opening of an objective of the arrangement 1 with a numerical aperture NA of 0.93.

The stacked antireflection layers 9, which forms the basis of FIG. 7a, comprises a first layer 10, placed on the carrier 8, made of magnesium fluoride with a layer thickness of 1336.8 nm, a second layer 11 made of tantalum pentoxide with a layer thickness of 303.8 nm, and a third layer 12 made of magnesium fluoride with a layer thickness of 1031.8 nm. The stacked antireflection layers 9 produce a transmission of 75%, which is almost constant over the entire angle range.

The stacked antireflection layers 9, which forms the basis of FIG. 7b, comprise a first layer 10, placed on the carrier 8, made of magnesium fluoride with a layer thickness of 1340.2 nm, a second layer 11 made of tantalum pentoxide with a layer thickness of 158.32 nm, and a third layer 12 made of magnesium fluoride with a layer thickness of 1029.26 nm. The stacked antireflection layers 9 produce a transmission of 85%, which is almost constant over the entire angle range.

The stacked antireflection layers 9, which forms the basis of FIG. 7c, comprise a first layer 10, placed on the carrier 8, made of magnesium fluoride with a layer thickness of 505.6 nm, a second layer 11 made of tantalum pentoxide with a layer thickness of 269.2 nm, and a third layer 12 made of magnesium fluoride with a layer thickness of 645.2 nm. The stacked antireflection layers 9 produce a transmission of 95%, which is almost constant over the entire angle range.

FIG. 8 shows an arrangement which can be used if as uniform as possible a transmission through the stacked antireflection layers 9, as is shown in FIGS. 7a to 7c, is to be attained. In this case, the optical element 6 can be placed between the illumination device 4 and the photomask 2, whereas the photomask 2 can be placed between the optical element 6 and the substrate 5.

What is claimed is:

1. An arrangement for the transfer of structural elements of a photomask onto a substrate, the arrangement comprising:
an illumination device;
a photomask with a plurality of structural elements, wherein radiation of the illumination device transfers the structural elements of the photomask onto a photoresist disposed over the substrate; and
an optical element between the illumination device and the substrate, wherein the optical element produces a local variation in the degree of transmission of the radiation.

2. The arrangement according to claim 1, wherein the optical element has a surface and wherein the optical element produces a local variation in the degree of transmission of the radiation as a function of an angle of incidence of the radiation, with respect to the surface.

3. The arrangement according to claim 1, wherein the optical element is located between the photomask and the substrate, and wherein an angle of incidence is caused by diffraction at the plurality of structural elements of the photomask, so that the photomask deflects, at various angles of reflection, diffraction orders of the radiation, diffracted at the structural elements, attenuated to different extents.

4. The arrangement according to claim 1, further comprising a first lens system between the illumination device and the photomask, and a second lens system between the optical element and the substrate.

5. The arrangement according to claim 1, wherein the optical element has a surface, and wherein the optical element produces a local variation in the degree of transmission of the radiation, independently of the angle of incidence of the radiation with respect to the surface.

6. The arrangement according to claim 5, wherein the optical element is located between the photomask and the substrate, and wherein the angle of incidence is caused by diffraction at the plurality of structural elements of the photomask, so that the photomask deflects, at various angles of reflection, diffraction orders of the radiation, diffracted at the structural elements, attenuated to the same extent.

7. The arrangement according to claim 5, wherein the optical element is located between the illumination device and the photomask.

8. The arrangement according to claim 7, further comprising a first lens system between the illumination device and the optical element, and a second lens system between the photomask and the substrate.

9. The arrangement according to claim 1, wherein the optical element comprises a carrier and stacked antireflection layers disposed thereon.

10. The arrangement according to claim 9, wherein the carrier comprises an optically transparent material.

11. The arrangement according to claim 10, wherein the optically transparent material comprises quartz glass.

12. The arrangement according to claim 9, wherein the stacked antireflection layers comprises a first layer over the carrier, a second layer over the first layer, and a third layer over the second layer.

13. The arrangement according to claim 12, wherein the first layer comprises magnesium fluoride.

14. The arrangement according to claim 12, wherein the second layer comprises tantalum pentoxide.

15. The arrangement according to claim 12, wherein the third layer comprises magnesium fluoride.

16. The arrangement according to claim 12, wherein the first layer comprises magnesium fluoride, the second layer comprises tantalum pentoxide and the third layer comprises magnesium fluoride.

17. The arrangement according to claim 12, wherein different sections of the carrier have a different layer thickness for the first layer.

18. The arrangement according to claim 17, wherein the different sections of the carrier have a different layer thickness for the second layer.

19. The arrangement according to claim 18, wherein the different sections of the carrier have a different layer thickness for the third layer.

20. The arrangement according to claim 1, wherein the illumination device comprises a dipole illumination device.

21. The arrangement according to claim 1, wherein the illumination device comprises a quadrupole illumination device.

22. The arrangement according to claim 1, wherein the illumination device comprises an annular illumination device.

23. The arrangement according to claim 1, wherein adjacent structural elements, in a first lateral direction, are at a first distance from one another, and in which adjacent structural elements, along a second lateral direction, are at a second distance from one another.

24. A method for the transfer of structural elements onto a substrate, the method comprising:
providing a photomask with a plurality of structural elements disposed thereon;
providing a substrate with a photoresist over the substrate;
transferring the structural elements of the photomask onto the photoresist by directing radiation through the photomask and through an optical element, wherein the optical element has a local variation in the degree of transmission of the radiation; and
modifying the substrate in relation to the structure elements.

25. The method according to claim 24, wherein the optical element has a surface and wherein the optical element produces a local variation in the degree of transmission of the radiation as a function of the angle of incidence of the radiation with respect to the surface.

26. The method according to claim 25, wherein the optical element located between the photomask and the substrate, and wherein the angle of incidence is caused by diffraction at the plurality of structural elements of the photomask, so that the photomask deflects, at various angles of reflection, diffraction orders of the radiation diffracted at the structural elements, which are attenuated to different extents.

27. The method according to claim 24, wherein the optical element has a surface and wherein the optical element produces a local variation in the degree of transmission of the radiation, independently of an angle of incidence of the radiation with respect to the surface.

28. The method according to claim 24, wherein the optical element comprises a carrier and stacked antireflection layers disposed thereover.

29. The method according to claim 28, wherein the carrier comprises an optically transparent material.

30. The method according to claim 29, wherein the optically transparent material comprises quartz glass.

31. The method according to claim 28, wherein the stacked antireflection layers comprise a first layer placed on the carrier, a second layer placed on the first layer, and a third layer placed on the second layer.

32. The method according to claim 31, wherein the first layer comprises magnesium fluoride.

33. The method according to claim 31, wherein the second layer comprises tantalum pentoxide.

34. The method according to claim 31, wherein the third layer comprises magnesium fluoride.

35. The method according to claim 31, wherein the carrier has a plurality of sections, each section having a different layer thickness for the individual first layer.

36. The method according to claim 35, wherein the plurality of sections of the carrier have a different layer thickness for the individual second layer.

37. The method according to claim 35, wherein the plurality of sections of the carrier have a different layer thickness for the individual third layer.

38. The method according to claim 24, wherein the radiation is generated by a dipole illumination device.

39. The method according to claim 24, wherein the radiation is generated by a quadrupole illumination device.

40. The method according to claim 24, wherein the radiation is generated by an annular illumination device.

41. The method according to claim 24, wherein adjacent structural elements in a first lateral direction are at a first distance from one another, and adjacent structural elements in a second lateral direction are at a second distance from one another.

42. A method for the transfer of structural elements onto a substrate, the method comprising:
providing a photomask with a plurality of structural elements disposed thereon;
providing a first substrate with a photoresist disposed over a surface thereof;
transferring the structural elements of the photomask onto the photoresist of the first substrate by directing radiation through the photomask thereby forming image elements on the first substrate;
measuring the image elements on the first substrate;
determining deviations of the obtained image elements on the first substrate, in comparison with nominal structures;
forming an optical element designed to correct the deviations of the obtained image elements;
providing a second substrate with a photoresist disposed over a surface thereof;
transferring the structural elements of the photomask onto the photoresist of the second substrate by directing radiation through the photomask and the optical element, wherein the optical element produces a local variation in the degree of transmission of the radiation; and
modifying the surface of the second substrate in relation to the structure elements.

43. The method according to claim 42, wherein the optical element produces a local variation in the degree of transmission of the radiation as a function of an angle of incidence of the radiation with respect to a surface of the optical element.

44. The method according to claim 43, wherein the optical element is placed between the photomask and the substrate, and wherein the angle of incidence is caused by diffraction at the plurality of structural elements of the photomask, so that the photomask deflects, at various angles of reflection, diffraction orders of the radiation, diffracted at the structural elements, attenuated to different extents.

45. The method according to claim 42, wherein the optical element produces a local variation in the degree of transmission of the radiation, independently of the angle of incidence of the radiation with respect to a surface of the optical element.

46. The method according to claim 42, wherein forming the optical element comprises providing a carrier with a surface, and forming stacked antireflection layers over the carrier.

47. The method according to claim 46, wherein the carrier comprises an optically transparent material.

48. The method according to claim 47, wherein the optically transparent material comprises quartz glass.

49. The method according to claim 46, wherein forming stacked antireflection layers comprises forming a first layer over the carrier, forming a second layer on the first layer, and forming a third layer on the second layer.

50. The method according to claim 49, wherein the first layer comprises magnesium fluoride.

51. The method according to claim 49, wherein the second layer comprises tantalum pentoxide.

52. The method according to claim 49, wherein the third layer comprises magnesium fluoride.

53. The method according to claim 49, wherein the carrier has a plurality of sections, which each have a different layer thickness for the first layer.

54. The method according to claim 53, wherein the plurality of sections of the carrier have a different layer thickness for the second layer.

55. The method according to claim 53, wherein the plurality of sections of the carrier have a different layer thickness for the third layer.

56. The method according to claim 42, wherein the radiation is generated by a dipole illumination device.

57. The method according to claim 42, wherein the radiation is generated by a quadrupole illumination device.

58. The method according to claim 42, wherein the radiation is generated by an annular illumination device.

59. The method according to claim 42, wherein adjacent structural elements in a first lateral direction are at a first distance from one another, and adjacent structural elements in a second lateral direction are at a second distance from one another.
